(19) United States
(12) Patent Application Publication
(10) Pub. No.: US 2023/0371289 A1
(43) Pub. Date: Nov. 16, 2023

(54) IMAGING DEVICE

(71) Applicant: Panasonic Intellectual Property Management Co., Ltd., Osaka (JP)

(72) Inventors: MASAYA HIRADE, Osaka (JP); HIROAKI IIJIMA, Nara (JP); YUKO KISHIMOTO, Osaka (JP); MASUMI IZUCHI, Osaka (JP)

(21) Appl. No.: 18/357,110

(22) Filed: Jul. 22, 2023

Related U.S. Application Data
(63) Continuation of application No. PCT/JP2021/040532, filed on Nov. 4, 2021.

(30) Foreign Application Priority Data
Feb. 12, 2021 (JP) 2021-021332

(51) Int. Cl. H10K 30/30; H10K 85/20; H10K 85/30

(52) U.S. Cl. CPC H10K 30/353; H10K 85/211; H10K 85/311; H10K 30/86

(57) ABSTRACT

An imaging device includes a photoelectric conversion element that includes a first electrode, a second electrode facing the first electrode, and a photoelectric conversion layer located between the first electrode and the second electrode; and a charge detection circuit that reads a charge generated in the photoelectric conversion element. The photoelectric conversion layer is a bulk heterojunction layer that contains a phthalocyanine derivative or a naphthalocyanine derivative and a fullerene polymer. In the fullerene polymer, a fullerene or a fullerene derivative is crosslinked by a crosslinking structure represented by general formula (1) below. In general formula (1), X is a bifunctional functional group.

[symbol]

NCH₂XCH₂N [symbol] (1)

### BACKGROUND

### 1. Technical Field

The present disclosure relates to an imaging device.

### 2. Description of the Related Art

Organic semiconductor materials have, for example, physical properties and functions that are not exhibited by existing inorganic semiconductor materials such as silicon. Therefore, organic semiconductor materials have been actively studied in recent years as semiconductor materials that can provide novel semiconductor devices and electronic equipment as disclosed in, for example, JANA ZAUMSEIL et. al., “Electron and Ambipolar Transport in Organic Field-Effect Transistors”, Chemical Reviews, American Chemical Society, 2007, Vol. 107, No. 4, pp. 1296-1323 (Non Patent Literature 1).

For example, it has been studied that organic semiconductor materials are formed into thin films and used as photoelectric conversion materials to provide photoelectric conversion elements. As disclosed in SERAP GUNES et. al., “Conjugated Polymer-Based Organic Solar Cells”, Chemical Reviews, American Chemical Society, 2007, Vol. 107, No. 4, pp. 1324-1338 (Non Patent Literature 2), a photoelectric conversion element that uses an organic material thin film extracts, as energy, charges which are carriers generated by light and thereby can be used as an organic thin-film solar cell. Alternatively, as disclosed in Japanese Patent Nos. 4677314, 5349156, and 5969843, such a photoelectric conversion element extracts, as electrical signals, charges generated by light and thereby can be used as an optical sensor of an imaging device or the like.

Furthermore, phthalocyanine derivatives and naphthalocyanine derivatives are known as organic semiconductor materials having sensitivity in the near-infrared light region. For example, Japanese Patent No. 5216279 discloses a naphthalocyanine derivative having an absorption maximum wavelength of 805 nm to 825 nm.

### SUMMARY

In one general aspect, the techniques disclosed here feature an imaging device including a photoelectric conversion element that includes a first electrode, a second electrode facing the first electrode, and a photoelectric conversion layer located between the first electrode and the second electrode; and a charge detection circuit that reads a charge generated in the photoelectric conversion element. The photoelectric conversion layer is a bulk heterojunction layer that contains a phthalocyanine derivative or a naphthalocyanine derivative and a fullerene polymer. In the fullerene polymer, a fullerene or a fullerene derivative is crosslinked by a crosslinking structure represented by general formula (1) below.

[symbol]

NCH₂XCH₂N [symbol] (1)

In general formula (1), X is a bifunctional functional group.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic sectional view illustrating an example of a photoelectric conversion element according to an embodiment;

FIG. 2 is a flowchart of a method for forming a photoelectric conversion layer according to an embodiment;

FIG. 3 is a schematic sectional view illustrating another example of a photoelectric conversion element according to an embodiment;

FIG. 4 is an exemplary energy band diagram in the photoelectric conversion element illustrated in FIG. 3;

FIG. 5 is a diagram illustrating an example of a circuit configuration of an imaging device according to an embodiment;

FIG. 6 is a schematic sectional view illustrating an example of a device structure of a pixel in an imaging device according to an embodiment;

FIG. 7 is a schematic view illustrating a change in the case where a photoelectric conversion layer containing a fullerene polymer according to an embodiment is heated; and

FIG. 8 is a schematic view illustrating a change in the case where a photoelectric conversion layer containing no fullerene polymer is heated.

### DETAILED DESCRIPTIONS

### Underlying Knowledge Forming Basis of the Present Disclosure

In organic semiconductor materials, changes in the molecular structures of the organic compounds used can cause changes in the energy levels. Therefore, for example, when an organic semiconductor material is used as a photoelectric conversion material, the absorption wavelengths of the material can be controlled, and thus the material can be made to have spectral sensitivity also in the near-infrared light region, where silicon (Si) does not have spectral sensitivity. Specifically, the use of organic semiconductor materials enables the utilization of light in a wavelength region that has not been used for photoelectric conversion to date to realize an increase in the efficiency of solar cells and optical sensors in the near-infrared light region. Therefore, in recent years, photoelectric conversion elements and imaging devices that use organic semiconductor materials having sensitivity in the near-infrared light region have been actively studied.

Phthalocyanine derivatives and naphthalocyanine derivatives have a large π-conjugated system and strong absorption, due to π-π* absorption, in the near-infrared light region and thus are promising candidates for materials used in imaging devices.

Meanwhile, when a photoelectric conversion element is applied to an imaging device, in general, a color filter, an on-chip lens, and the like are formed above a photoelectric conversion layer. For example, when a color filter is formed above a photoelectric conversion layer, the process temperature is higher than or equal to about 200° C., and the photoelectric conversion layer is also required to have heat resistance to the same temperature.

Lionel Derue et. al., “Thermal Stabilisation of Polymer-Fullerene Bulk Heterojunction Morphology for Efficient Photovoltaic Solar Cells”, Advanced Materials, Wiley-VCH, 2014, Vol. 26, pp. 5831-5838 (Non Patent Literature 3) discloses that heat resistance of a photoelectric conversion film is improved by polymerizing a fullerene. However, since the photoelectric conversion film in Non Patent Literature 3 is used for organic solar cells, dark current is not described in Non Patent Literature 3.

The present inventors have found that even after a photoelectric conversion layer is exposed to a high temperature, for example, as in an imaging device produced through a step of heating a photoelectric conversion layer to a high temperature, an imaging device having a high photoelectric conversion efficiency and capable of suppressing dark current can be realized by selecting materials contained in the photoelectric conversion layer.

In view of the above, the present disclosure provides an imaging device having a high photoelectric conversion efficiency and capable of suppressing dark current even in the case where a photoelectric conversion layer is exposed to a high temperature.

The summary of an aspect according to the present disclosure is as follows.

An imaging device according to an aspect of the present disclosure includes a photoelectric conversion element that includes a first electrode, a second electrode facing the first electrode, and a photoelectric conversion layer located between the first electrode and the second electrode; and a charge detection circuit that reads a charge generated in the photoelectric conversion element. The photoelectric conversion layer is a bulk heterojunction layer that contains a phthalocyanine derivative or a naphthalocyanine derivative and a fullerene polymer. In the fullerene polymer, a fullerene or a fullerene derivative is crosslinked by a crosslinking structure represented by general formula (1) below.

[symbol]

NCH₂XCH₂N [symbol] (1)

In general formula (1), X is a bifunctional functional group.

In this case, the phthalocyanine derivative or naphthalocyanine derivative contained in the photoelectric conversion layer easily absorbs visible light and/or near-infrared light, and thus the imaging device can realize a high photoelectric conversion efficiency. Furthermore, since the fullerene polymer is contained in the photoelectric conversion layer, even when the photoelectric conversion layer is heated, the movement of the phthalocyanine derivative or naphthalocyanine derivative due to heating is limited, and thus an aggregation of the phthalocyanine derivative or naphthalocyanine derivative in the photoelectric conversion layer is suppressed. Therefore, even after the photoelectric conversion layer is exposed to a high temperature, the imaging device can suppress an increase in dark current and a decrease in the photoelectric conversion efficiency. Thus, an imaging device having a high photoelectric conversion efficiency and capable of suppressing dark current can be realized.

For example, in general formula (1), X may be an alkylene group or an arylene group.

In this case, portions of the crosslinking structure have a low molecular weight, and the crosslinking structure is less likely to hinder the charge transport in the photoelectric conversion layer.

For example, the photoelectric conversion layer may contain a compound represented by general formula (2) below as the phthalocyanine derivative or a compound represented by general formula (3) below as the naphthalocyanine derivative.

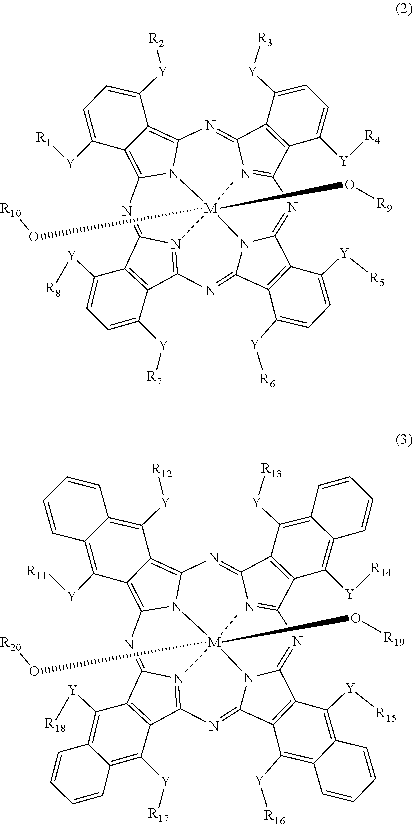

In general formulae (2) and (3), R₁ to R₈ and R₁₁ to R₁₈ are each independently an alkyl group; M is Si or Sn; Y is S or O; Z is S or O; and R₉, R₁₀, R₁₉, and R₂₀ are each any one of substituents represented by general formulae (4) to (6) below. In general formulae (4) to (6), R₂₁ to R₂₃ are each independently an alkyl group or an aryl group; and R₂₄ to R₂₆ are each independently an aryl group.

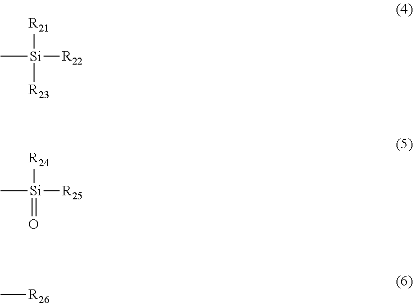

In this case, the imaging device can have a high photoelectric conversion efficiency in the near-infrared light region.

For example, in general formulae (2) and (3), M may be Si, Y may be S, and Z may be O.

In this case, the phthalocyanine derivative or naphthalocyanine derivative used in the imaging device can be easily synthesized.

For example, the imaging device may include a charge-blocking layer between the photoelectric conversion layer and one of the first electrode and the second electrode.

In this case, the imaging device can further suppress dark current.

Embodiments will be specifically described below with reference to the drawings.

Note that the embodiments described below are all general or specific examples. Numerical values, shapes, materials, components, arrangement positions and connection forms of the components, steps, the order of the steps, and the like described in the embodiments below are merely examples and are not intended to limit the present disclosure. Among the components in the following embodiments, components that are not described in an independent claim are described as optional components. The drawings are not necessarily strict illustrations. Therefore, for example, the scales etc. in the drawings do not always coincide with each other. In the drawings, substantially the same components are assigned the same reference signs, and redundant description thereof may be omitted or simplified.

In the present specification, terms representing the relations between components, terms representing the shapes of components, and numerical ranges do not represent only their strict meanings but are intended to include those in substantially the same range, for example, those with a few percent difference.

In the present specification, the terms “above” and “below” do not refer to an upward direction (vertically above) and a downward direction (vertically below), respectively, in an absolute spatial recognition but are used as terms specified by relative positional relations on the basis of the order of stacking in a stack structure. Specifically, the term “above” is used to refer to the light-receiving side of an imaging device, and the term “below” is used to refer to the opposite side to the light-receiving side. Note that the terms such as “above” and “below” are used only to specify the mutual arrangement of members and are not intended to limit the posture of the imaging device during use. The terms “above” and “below” are used not only when two components are disposed with a space therebetween and another component is present between the two components but also when two components are disposed to be in close contact with each other, so that the two components contact each other.

### EMBODIMENTS

Embodiments will now be described.

### Photoelectric Conversion Element

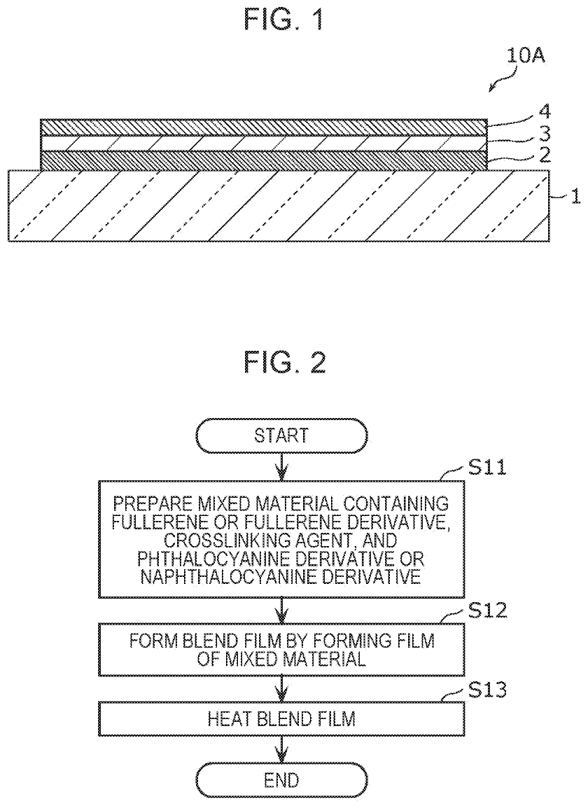

Hereinafter, a photoelectric conversion element included in an imaging device according to an embodiment will be described with reference to the drawings. The photoelectric conversion element according to this embodiment is, for example, a charge-reading type photoelectric conversion element. FIG. 1 is a schematic sectional view illustrating a photoelectric conversion element 10A which is an example of the photoelectric conversion element according to the embodiment.

The photoelectric conversion element 10A according to the embodiment includes an upper electrode 4 and a lower electrode 2 which are a pair of electrodes disposed to face each other and a photoelectric conversion layer 3 located between the pair of electrodes. The upper electrode 4 is an example of the first electrode, and the lower electrode 2 is an example of the second electrode. The photoelectric conversion layer 3 is constituted by a bulk heterojunction layer that contains a phthalocyanine derivative or naphthalocyanine derivative and a fullerene polymer. The bulk heterojunction layer is a layer having a bulk heterojunction structure of a donor organic semiconductor and an acceptor organic semiconductor, and, for example, the whole thereof constitutes the bulk heterojunction structure. For example, the phthalocyanine derivative or the naphthalocyanine derivative is a compound used as the donor organic semiconductor, and the fullerene polymer is a compound used as the acceptor organic semiconductor. Hereinafter, a description will be made of an example in which a phthalocyanine derivative or a naphthalocyanine derivative is used as a donor organic semiconductor, and a fullerene polymer is used as an acceptor organic semiconductor. Details about the phthalocyanine derivative, the naphthalocyanine derivative, and the fullerene polymer will be described later. Note that a phthalocyanine derivative or a naphthalocyanine derivative may be used as an acceptor organic semiconductor, and a fullerene polymer may be used as a donor organic semiconductor.

The photoelectric conversion element 10A according to the embodiment is supported by, for example, a support substrate 1. The support substrate 1 is transparent to, for example, light at wavelengths that can be absorbed by the photoelectric conversion layer 3, and light enters the photoelectric conversion element 10A through the support substrate 1. The support substrate 1 can be a substrate used for ordinary photoelectric conversion elements and may be, for example, a glass substrate, a quartz substrate, a semiconductor substrate, or a plastic substrate. Note that the term “transparent” in the present specification means that transmitting at least a portion of light at wavelengths that can be absorbed by the photoelectric conversion layer 3 and does not necessarily mean transmitting light over the entire wavelength range.

The components of the photoelectric conversion element 10A according to this embodiment will be described below.

First, the photoelectric conversion layer 3 will be described. The photoelectric conversion layer 3 generates charges as a result of photoelectric conversion. The photoelectric conversion layer 3 is constituted by a bulk heterojunction layer in which a donor organic semiconductor and an acceptor organic semiconductor are blended.

The donor organic semiconductor and the acceptor organic semiconductor according to this embodiment will be specifically described below.

First, the acceptor organic semiconductor according to this embodiment will be described. The acceptor organic semiconductor is mainly typified by an electron-transporting organic compound and is an organic compound having electron-accepting properties. More specifically, the acceptor organic semiconductor is an organic compound having a higher electron affinity when two organic compounds are used in contact with each other. Therefore, as the acceptor organic semiconductor, any organic compound can be used as long as the organic compound is an electron-accepting organic compound. Examples of the organic compounds used as the acceptor organic semiconductor include fullerene, fullerene derivatives, fused aromatic carbocyclic compounds (such as naphthalene derivatives, anthracene derivatives, phenanthrene derivatives, tetracene derivatives, pyrene derivatives, perylene derivatives, and fluoranthene derivatives), five- to seven-membered heterocyclic compounds containing a nitrogen atom, an oxygen atom, or a sulfur atom (such as pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, and tribenzazepine), polyarylene compounds, fluorene compounds, cyclopentadiene compounds, silyl compounds, and metal complexes having a nitrogen-containing heterocyclic compound as a ligand. Note that these are only non-limiting examples, and an organic compound having a higher electron affinity than the organic compound used as the donor organic semiconductor may be used as the acceptor organic semiconductor.

The photoelectric conversion element 10A according to the embodiment includes a fullerene polymer in which a fullerene or a fullerene derivative is crosslinked by a crosslinking structure represented by general formula (1) below. In the embodiment, for example, the acceptor organic semiconductor contains the fullerene polymer as a main component.

[symbol]

NCH₂XCH₂N [symbol] (1)

The crosslinking structure represented by general formula (1) is a functional group having nitrogen atoms at both ends. In the crosslinking structure represented by general formula (1), the nitrogen atoms at both ends are each covalently bonded to X, which is a bifunctional functional group, through a methylene group. In the fullerene polymer, the nitrogen atoms at both ends of the crosslinking structure are each covalently bonded to two carbon atoms of the fullerene skeleton of a fullerene or a fullerene derivative to form a three-membered ring structure. In general formula (1), X is a bifunctional functional group and is, for example, a bifunctional aliphatic or aromatic hydrocarbon group such as an alkylene group or an arylene group. When X is an alkylene group or an arylene group, portions of the crosslinking structure have a low molecular weight, and the crosslinking structure is less likely to hinder the charge transport in the photoelectric conversion layer 3. Note that some of hydrogen atoms of the hydrocarbon group may be substituted with substituents, and X is not limited to a hydrocarbon group and may be a functional group having a heteroatom. The fullerene polymer is a compound having a composition represented by FLₘRₘ₋₁ where FL represents a fullerene or a fullerene derivative, and R represents a crosslinking structure. In this case, m is an integer greater than or equal to 2. That is, the fullerene polymer is a dimer or higher polymer of a fullerene or a fullerene derivative. Examples of the fullerene include C60 fullerene and C70 fullerene. An example of the fullerene derivative is [6,6]-phenyl-C₆₁-butyric acid methyl ester (PCBM).

Thus, since the photoelectric conversion layer 3 contains an acceptor organic semiconductor containing a fullerene polymer in which a fullerene or fullerene derivative that is likely to accept charges is crosslinked, the movement of electrons generated upon light absorption by the donor organic semiconductor can be smoothly performed between the donor organic semiconductor and the acceptor organic semiconductor to achieve a higher photoelectric conversion efficiency.

The molecular weight of X in general formula (1) is, for example, greater than or equal to 14 and less than or equal to 300 from the viewpoint that the crosslinking structure is less likely to hinder the charge transport in the photoelectric conversion layer 3.

The fullerene polymer according to this embodiment is represented by, for example, general formula (7) below.

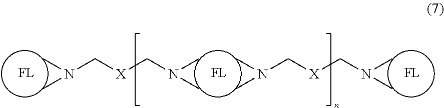

X in general formula (7) is the same as X in general formula (1). The circle surrounding FL in general formula (7) represents a fullerene or a fullerene derivative, and the fullerene or the fullerene derivative forms a three-membered ring structure together with a nitrogen atom of the crosslinking structure. n is an integer greater than or equal to 0. The fullerene polymer may be linear as in general formula (7) or may have branching in which three or more fullerene or fullerene derivative molecules are crosslinked with one fullerene or fullerene derivative molecule.

In this embodiment, the fullerene polymer represented by general formula (7) may be, for example, any one of compounds represented by general formulae (8), (9), and (10) below.

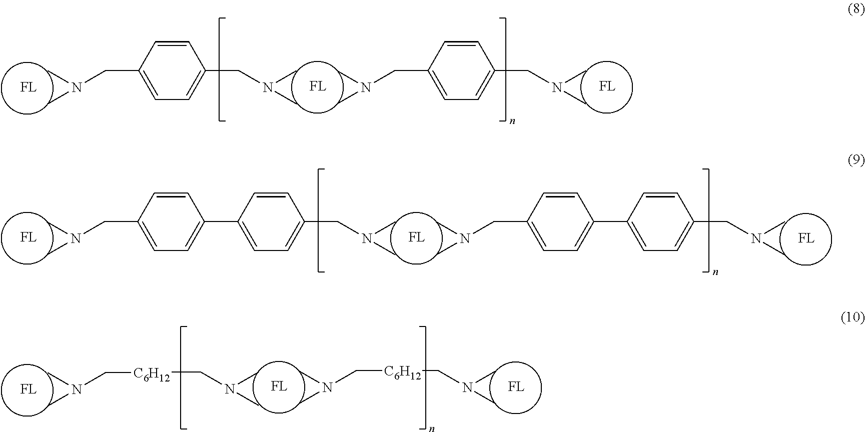

The fullerene polymer represented by general formula (8) is a compound in which X in general formula (7) is a phenylene group. The fullerene polymer represented by general formula (9) is a compound in which X in general formula (7) is a biphenylene group. The fullerene polymer represented by general formula (10) is a compound in which X in general formula (7) is a hexylene group. The fullerene polymers represented by general formulae (8), (9), and (10) are linear but may have branching.

When the fullerene polymer is any one of the compounds represented by general formulae (8), (9), and (10), the photoelectric conversion layer 3 has improved heat resistance, and the fullerene polymer can be easily synthesized.

The method for forming the fullerene polymer is described layer, but the fullerene polymer can be formed by, for example, forming a film that contains a crosslinking agent and a fullerene or a fullerene derivative by a coating method, followed by a crosslinking reaction.

The acceptor organic semiconductor may contain a material other than the fullerene polymer represented by general formula (7). For example, the acceptor organic semiconductor may contain a fullerene monomer or a fullerene derivative monomer. The acceptor organic semiconductor may contain at least one of the above organic compounds described as examples of organic compounds used as the acceptor organic semiconductor.

Next, the donor organic semiconductor according to this embodiment will be described. The donor organic semiconductor is mainly typified by a hole-transporting organic compound and is an organic compound having electron-donating properties. More specifically, the donor organic semiconductor is an organic compound having a lower ionization potential when two organic compounds are used in contact with each other. Therefore, as the donor organic semiconductor, any organic compound can be used as long as the organic compound is an electron-donating organic compound. Examples of the organic compounds that can be used as the donor organic semiconductor include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, naphthalocyanine compounds, cyanine compounds, merocyanine compounds, oxonol compounds, polyamine compounds, indole compounds, pyrrole compounds, pyrazole compounds, polyarylene compounds, fused aromatic carbocyclic compounds (naphthalene derivatives, anthracene derivatives, phenanthrene derivatives, tetracene derivatives, pyrene derivatives, perylene derivatives, and fluoranthene derivatives), and metal complexes having a nitrogen-containing heterocyclic compound as a ligand. Note that these are only non-limiting examples, and an organic compound having a lower ionization potential than the organic compound used as the acceptor organic semiconductor may be used as the donor organic semiconductor.

The photoelectric conversion element 10A according to the embodiment includes a phthalocyanine derivative or a naphthalocyanine derivative. In the embodiment, for example, the donor organic semiconductor contains a phthalocyanine derivative or a naphthalocyanine derivative as a main component.

In the embodiment, the donor organic semiconductor may contain a compound represented by general formula (2) below as the phthalocyanine derivative or a compound represented by general formula (3) below as the naphthalocyanine derivative.

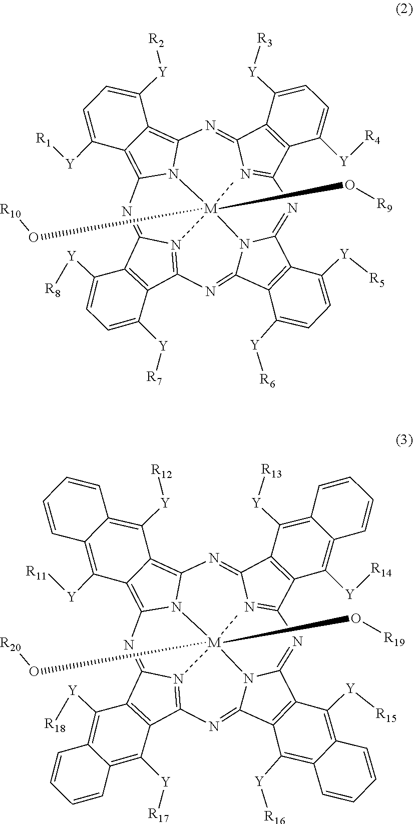

R₁ to R₈ and R₁₁ to R₁₈ are each independently an alkyl group; M is Si or Sn; Y is S or O; Z is S or O; and R₉, R₁₀, R₁₉, and R₂₀ are each any one of substituents represented by general formulae (4) to (6) below.

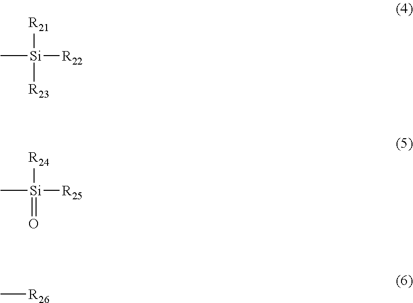

R₂₁ to R₂₃ are each independently an alkyl group or an aryl group; and R₂₄ to R₂₆ are each independently an aryl group. Since the compound represented by general formula (2) and the compound represented by general formula (3) have electron-donating alkoxy groups or alkylsulfanyl groups in side chains at the a positions, the absorption wavelength is increased, and the absorption coefficient tends to be high in the near-infrared light region.

In general formulae (2) and (3), M may be Si, Y may be S, and Z may be O. In this case, the phthalocyanine derivative or the naphthalocyanine derivative can be easily synthesized.

In at least one of R₂₁ to R₂₃ in general formula (4), at least one of R₂₄ or R₂₅ in general formula (5), and R₂₆ in general formula (6), at least one hydrogen atom may be substituted with an electron-withdrawing group. In this case, the electron-withdrawing ability of an axial ligand included in the phthalocyanine derivative or the naphthalocyanine derivative increases, the electron density of the phthalocyanine ring or the naphthalocyanine ring decreases, and the energy band gap of the phthalocyanine derivative or the naphthalocyanine derivative narrows. As a result, the absorption wavelength of the phthalocyanine derivative or the naphthalocyanine derivative is further increased, and the dark current in the imaging device can be suppressed. Examples of the electron-withdrawing group include a cyano group, a fluoro group, and a carbonyl group. The electron-withdrawing group may be a cyano group or a fluoro group from the viewpoint of high electron-withdrawing ability.

In this embodiment, the phthalocyanine derivative or the naphthalocyanine derivative may be, for example, any one of compounds represented by structural formulae (11) to (20) below.

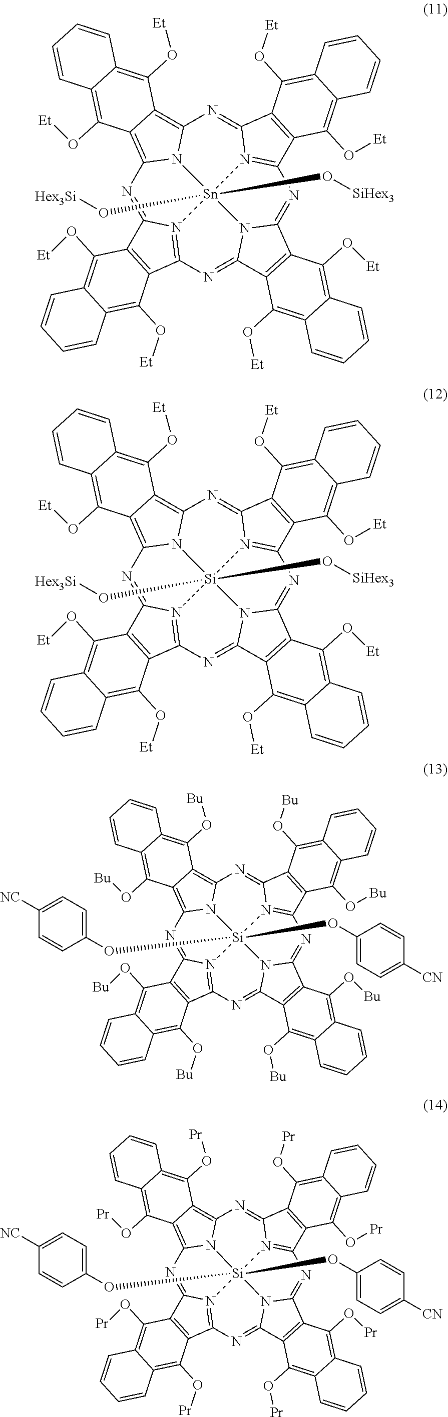

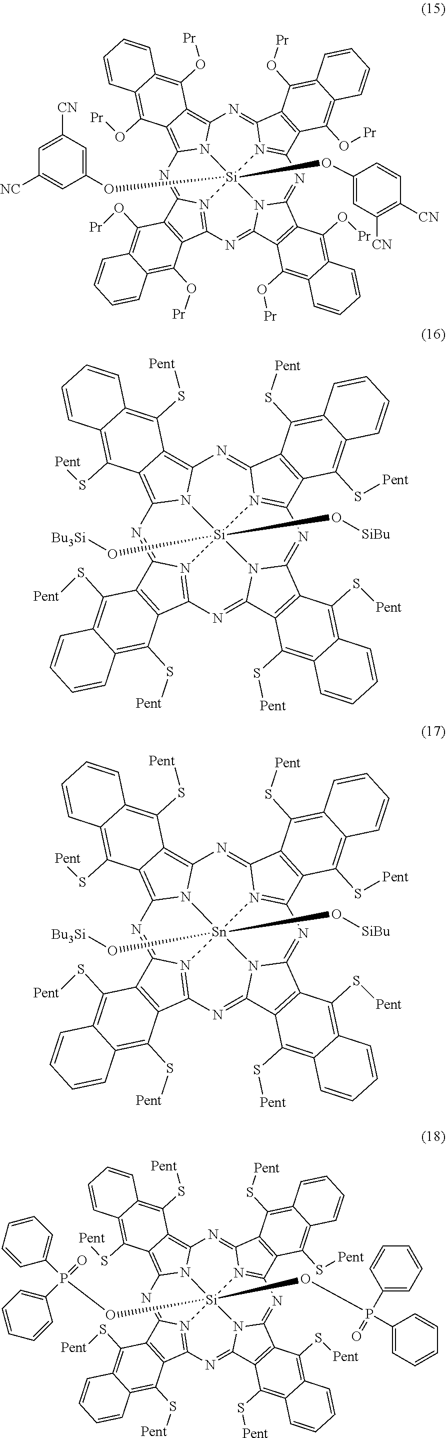

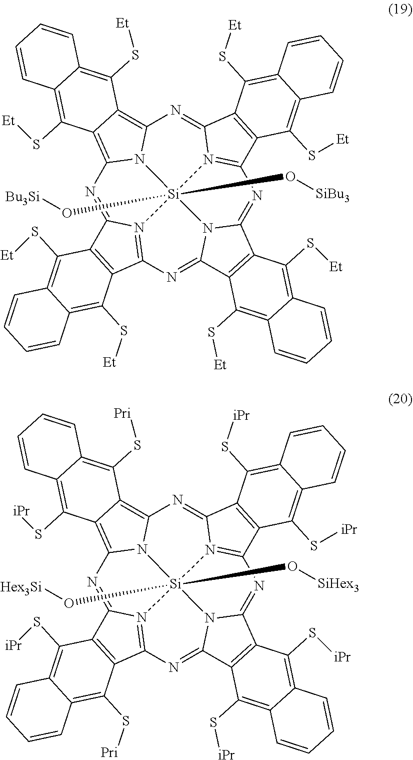

When the phthalocyanine derivative or the naphthalocyanine derivative is any one of the compounds represented by structural formulae (11) to (20), a high photoelectric conversion efficiency can be achieved in the near-infrared light region. The compounds represented by structural formulae (11) to (20) can be synthesized by publicly known synthesis methods or synthesis methods described in Examples below.

The donor organic semiconductor may contain a material other than the phthalocyanine derivative or the naphthalocyanine derivative. For example, the donor organic semiconductor may contain at least one of the above organic compounds described as examples of organic compounds used as the donor organic semiconductor.

In a bulk heterojunction layer, charges may be generated in some cases even in a dark state when the donor organic semiconductor and the acceptor organic semiconductor come in contact with each other.

This is due to thermal excitation from the highest occupied molecular orbital (HOMO) energy level of the donor organic semiconductor to the lowest unoccupied molecular orbital (LUMO) energy level of the acceptor organic semiconductor, and a smaller energy difference between the two generates a larger number of charges, and the dark current increases. When a fullerene or a fullerene derivative is crosslinked, 71 conjugation of the fullerene skeleton is interrupted, and thus the conjugation narrows and the LUMO energy level may decrease. As a result, the difference between the HOMO energy level of the donor organic semiconductor material and the LUMO energy level of the fullerene polymer increases, the generation of charges due to thermal excitation is suppressed, and the dark current can be suppressed.

When the bulk heterojunction layer contains a large amount of an acceptor organic semiconductor, such as a fullerene polymer, from the viewpoint of charge mobility, the element resistance can be reduced.

The photoelectric conversion layer 3 can be formed by, for example, a coating method such as spin-coating, or a vacuum deposition method of performing heating under vacuum to vaporize materials of the layer and to deposit the materials on a substrate. The deposition method may be employed in consideration of preventing entry of impurities and forming multiple layers for higher functionality with a higher degree of freedom. The deposition apparatus used may be a commercially available apparatus. During the deposition, the temperature of the deposition source may be higher than or equal to 100° C. and lower than or equal to 500° C. and may be higher than or equal to 150° C. and lower than or equal to 400° C. During the deposition, the degree of vacuum may be higher than or equal to 1×10⁻⁴ Pa and lower than or equal to 1 Pa, and may be higher than or equal to 1×10⁻³ Pa and lower than or equal to 0.1 Pa. The photoelectric conversion layer 3 may be formed by a method of adding, for example, metal fine particles to the deposition source to increase the deposition rate.

The blending ratio of the materials of the photoelectric conversion layer 3 is expressed in terms of weight ratio in the case of the coating method, or in terms of volume ratio in the case of the deposition method. More specifically, in the case of the coating method, the blending ratio is determined using the weights of the materials during preparation of the solution, and in the case of the deposition method, the blending ratio of the materials is determined during deposition while the thicknesses of the deposition layers of the materials are monitored with a layer thickness gauge.

The photoelectric conversion layer 3 containing a fullerene polymer may be directly formed by the method described above. Alternatively, a blend film of a fullerene or a fullerene derivative and a crosslinking agent that crosslinks the fullerene or fullerene derivative may be formed, and a crosslinking reaction may be caused to proceed by energy such as heat or light to form a fullerene polymer in the photoelectric conversion layer 3. In this manner, the fullerene polymer can be easily formed. FIG. 2 is a flowchart illustrating an example of a method for forming the photoelectric conversion layer 3 according to this embodiment.

As illustrated as an example in FIG. 2, in the method for forming the photoelectric conversion layer 3, first, a mixed material containing a fullerene or fullerene derivative, a crosslinking agent, and a phthalocyanine derivative or naphthalocyanine derivative is prepared as the material of the photoelectric conversion layer 3 (step S11). Here, the crosslinking agent is represented by general formula (21) below.

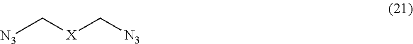

X in general formula (21) is the same as X in general formula (1). N₃ is an azi group. When the crosslinking agent represented by general formula (21) is used in the formation of the fullerene polymer, the crosslinking agent can be removed by heat, and thus unreacted crosslinking agent is unlikely to remain in the photoelectric conversion layer 3. Accordingly, the influence of hindering the charge transport due to the crosslinking agent remaining in the photoelectric conversion layer 3 can be reduced.

In the embodiment, the crosslinking agent represented by general formula (21) may be, for example, any one of compounds represented by structural formulae (22) to (24) below.

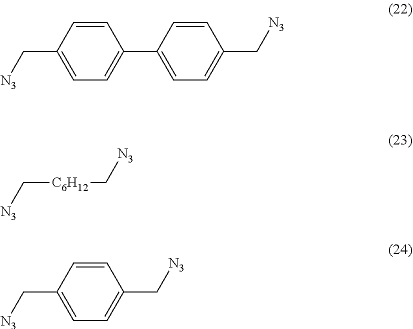

The crosslinking agents which are the compounds represented by structural formulae (22) to (24) have a relatively low molecular weight. Thus, the crosslinking agents are even less likely to remain in the photoelectric conversion layer 3 after the formation of the photoelectric conversion layer 3. Accordingly, the influence of hindering the charge transport due to the crosslinking agent remaining in the photoelectric conversion layer 3 can be further reduced.

Next, in the method for forming the photoelectric conversion layer 3, a blend film is formed by forming a film of the prepared mixed material on a layer under the photoelectric conversion layer 3, for example, on a lower electrode, a charge-blocking layer, or the like (step S12). The blend film is formed by, for example, applying a mixed material solution obtained by adding a solvent to the mixed material prepared in step S11. The application is performed by, for example, a spin-coating method in air, an N₂ atmosphere, or the like. The rotational speed in the spin-coating method is, for example, greater than or equal to 300 rpm and less than or equal to 3,000 rpm. The film of the mixed material may be formed by a method other than the spin-coating method.

Next, the formed blend film is heated (step S13). As a result, the fullerene or the fullerene derivative is crosslinked by the crosslinking agent to form a fullerene polymer in the blend film. Specifically, two azi groups of the crosslinking agent each react with the fullerene or the fullerene derivative to form a three-membered ring structure together with two carbon atoms of the fullerene or the fullerene derivative. Thus, the fullerene or the fullerene derivative is crosslinked by the crosslinking agent. As a result, the photoelectric conversion layer 3 containing a fullerene polymer is obtained. The temperature and time during heating in step S13 may be set on the basis of, for example, the half-life of the crosslinking agent.

As described above, in this embodiment, the fullerene polymer is, for example, a crosslinking reaction product of a fullerene or a fullerene derivative and the crosslinking agent represented by general formula (21).

Next, the upper electrode 4 and the lower electrode 2 will be described.

At least one of the upper electrode 4 or the lower electrode 2 is a transparent electrode formed of a conductive material that is transparent to light at the response wavelengths. A bias voltage is applied to the lower electrode 2 and the upper electrode 4 through wiring (not illustrated). For example, the bias voltage is set in view of polarity such that, of the charges generated in the photoelectric conversion layer 3, electrons move to the upper electrode 4 and holes move to the lower electrode 2. Alternatively, the bias voltage may be set such that, of the charges generated in the photoelectric conversion layer 3, holes move to the upper electrode 4 and electrons move to the lower electrode 2.

The bias voltage may be applied such that the intensity of the electric field generated in the photoelectric conversion element 10A, specifically, the value determined by dividing the applied voltage by the distance between the lower electrode 2 and the upper electrode 4, is in a range of greater than or equal to 1.0×10³ V/cm and less than or equal to 1.0×10⁷ V/cm, or in a range of greater than or equal to 1.0×10⁴ V/cm and less than or equal to 1.0×10⁶ V/cm. The adjustment of the magnitude of the bias voltage in this manner enables charges to efficiently move to the upper electrode 4, thus extracting signals corresponding to the charges to the outside.

The materials of the lower electrode 2 and the upper electrode 4 may be transparent conducting oxides (TCO) having high transmittances for light in the near-infrared light region and having low resistance values. Metal thin films made of gold (Au) or the like may be used as transparent electrodes; however, in some cases where a transmittance of greater than or equal to 90% for light in the near-infrared light region is attempted to be achieved, the resistance value may excessively increase, compared with the cases where transparent electrodes are formed so as to have a transmittance of 60% to 80%. Accordingly, compared with metal materials such as Au, TCO provides transparent electrodes having high transparency to near-infrared light and having low resistance values. Examples of TCO include, but are not particularly limited to, indium tin oxide (ITO), indium zinc oxide (IZO), aluminum-doped zinc oxide (AZO), fluorine-doped tin oxide (FTO), SnO₂, TiO₂, and ZnO₂. Note that the lower electrode 2 and the upper electrode 4 may be formed of one or a combination of a plurality of materials appropriately selected from TCO and metal materials, such as Au, in accordance with the desired transmittance

Note that the materials used for the lower electrode 2 and the upper electrode 4 are not limited to the above-described conductive materials that are transparent to near-infrared light and may be other materials.

Various methods are used for forming the lower electrode 2 and the upper electrode 4 depending on the materials used. For example, in the case of using ITO, an electron beam method, a sputtering method, a resistance heating deposition method, a chemical reaction method such as a sol-gel method, or a method such as coating with a dispersion of indium tin oxide may be used. In this case, after the formation of an ITO film, the ITO film may be further subjected to UV-ozone treatment, plasma treatment, or the like.

According to the photoelectric conversion element 10A, for example, photoelectric conversion occurs in the photoelectric conversion layer 3 upon entry of light through the support substrate 1 and the lower electrode 2 and/or light through the upper electrode 4. Of the resulting hole-electron pairs, which are pairs of charges, the holes are collected to the lower electrode 2, and the electrons are collected to the upper electrode 4. Thus, light that enters the photoelectric conversion element 10A can be detected by, for example, measuring the potential of the lower electrode 2.

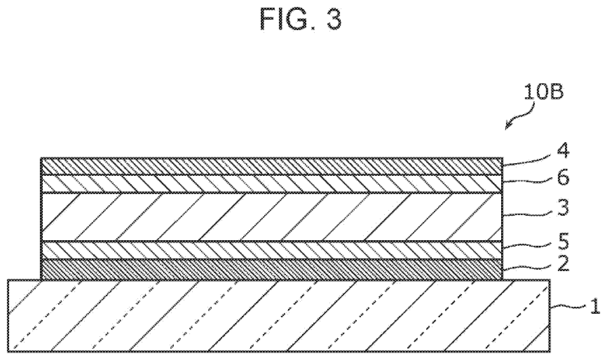

The photoelectric conversion element 10A may further include an electron-blocking layer 5 (refer to FIG. 3) and a hole-blocking layer 6 (refer to FIG. 3) described layer. The electron-blocking layer 5 and the hole-blocking layer 6 sandwich the photoelectric conversion layer 3, thereby suppressing injection of electrons from the lower electrode 2 into the photoelectric conversion layer 3 and injection of holes from the upper electrode 4 into the photoelectric conversion layer 3. As a result, the dark current can be suppressed. Details of the electron-blocking layer 5 and the hole-blocking layer 6 will be described later and are not described here.

Next, another example of the photoelectric conversion element according to this embodiment will be described. FIG. 3 is a schematic sectional view illustrating a photoelectric conversion element 10B, which is another example of the photoelectric conversion element according to the embodiment.

In the photoelectric conversion element 10B illustrated in FIG. 3, the same components as those in the photoelectric conversion element 10A illustrated in FIG. 1 are assigned the same reference numerals.

As illustrated in FIG. 3, the photoelectric conversion element 10B according to this embodiment includes a lower electrode 2 and an upper electrode 4 as a pair of electrodes, and a photoelectric conversion layer 3 disposed between the pair of electrodes. The photoelectric conversion element 10B further includes an electron-blocking layer 5 disposed between the lower electrode 2 and the photoelectric conversion layer 3, and a hole-blocking layer 6 disposed between the upper electrode 4 and the photoelectric conversion layer 3. The electron-blocking layer 5 and the hole-blocking layer 6 are examples of the charge-blocking layer. Details of the lower electrode 2, the upper electrode 4, and the photoelectric conversion layer 3 are the same as those described in the photoelectric conversion element 10A and are not described here.

The electron-blocking layer 5 is provided in order to reduce dark current caused by injection of electrons from the lower electrode 2 and suppresses injection of electrons from the lower electrode 2 into the photoelectric conversion layer 3. The electron-blocking layer 5 further has a function of transporting holes generated in the photoelectric conversion layer 3 into the lower electrode 2. The electron-blocking layer 5 may be formed of a donor semiconductor or a hole-transporting organic compound such as the material described in the above donor organic semiconductor.

The hole-blocking layer 6 is provided in order to reduce dark current caused by injection of holes from the upper electrode 4 and suppresses injection of holes from the upper electrode 4 into the photoelectric conversion layer 3. The hole-blocking layer 6 further has a function of transporting electrons generated in the photoelectric conversion layer 3 into the upper electrode 4. The material of the hole-blocking layer 6 may be, for example, an organic substance such as copper phthalocyanine, chloroaluminum phthalocyanine (ClAlPc), 3,4,9,10-perylenetetracarboxylic dianhydride (PTCDA), an acetylacetonate complex, bathocuproine (BCP), or tris(8-quinolinolate)aluminum (Alq); an organometallic compound; or an inorganic substance such as MgAg or MgO. The hole-blocking layer 6 may be formed of an acceptor semiconductor or an electron-transporting organic compound such as the material described in the above acceptor organic semiconductor.

In order not to hinder light absorption by the photoelectric conversion layer 3, the hole-blocking layer 6 may have a high transmittance for light in the wavelength region for photoelectric conversion, a material that does not have absorption in the visible light region may be selected as the material of the hole-blocking layer 6, and the thickness of the hole-blocking layer 6 may be reduced. The thickness of the hole-blocking layer 6 depends on, for example, the configuration of the photoelectric conversion layer 3 and the thickness of the upper electrode 4 and may be, for example, greater than or equal to 2 nm and less than or equal to 50 nm.

When the electron-blocking layer 5 is formed, the material of the lower electrode 2 is selected from the above-described materials in consideration of, for example, the adhesiveness to the electron-blocking layer 5, electron affinity, ionization potential, and stability. The same applies to the upper electrode 4 when the hole-blocking layer 6 is formed.

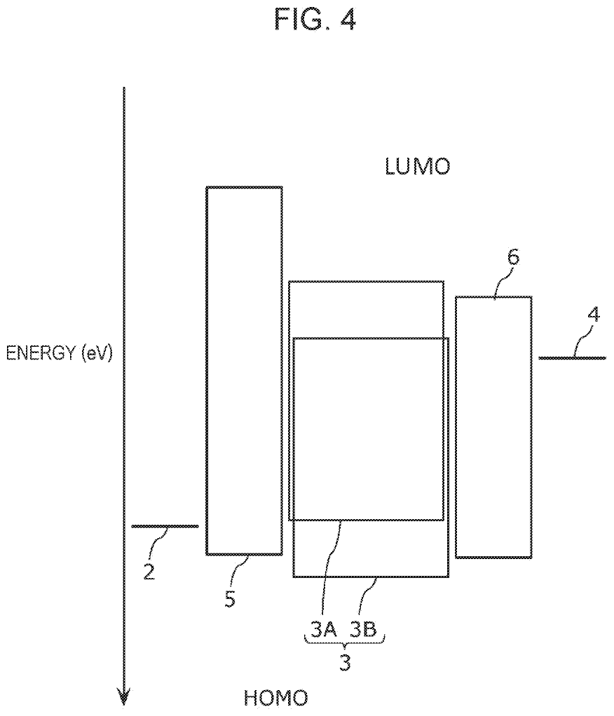

FIG. 4 illustrates an example of a schematic energy band diagram of the photoelectric conversion element 10B having the configuration illustrated in FIG. 3.

As illustrated in FIG. 4, in the photoelectric conversion element 10B, the HOMO energy level of the electron-blocking layer 5 is lower than the HOMO energy level of a donor organic semiconductor 3A contained in the photoelectric conversion layer 3. In addition, the LUMO energy level of the electron-blocking layer 5 is higher than the LUMO energy level of the donor organic semiconductor 3A.

In the photoelectric conversion element 10B, the LUMO energy level of the hole-blocking layer 6 is higher than the LUMO energy level of an acceptor organic semiconductor 3B contained in the photoelectric conversion layer 3.

In the photoelectric conversion element 10B, the positions of the electron-blocking layer 5 and the hole-blocking layer 6 may be exchanged. Specifically, the electron-blocking layer 5 may be disposed between the upper electrode 4 and the photoelectric conversion layer 3, and the hole-blocking layer 6 may be disposed between the lower electrode 2 and the photoelectric conversion layer 3. The photoelectric conversion element 10B may include only one of the electron-blocking layer 5 and the hole-blocking layer 6.

### Imaging Device

Next, an imaging device according to this embodiment will be described with reference to the drawings. The imaging device according to this embodiment is, for example, a charge-reading type imaging device.

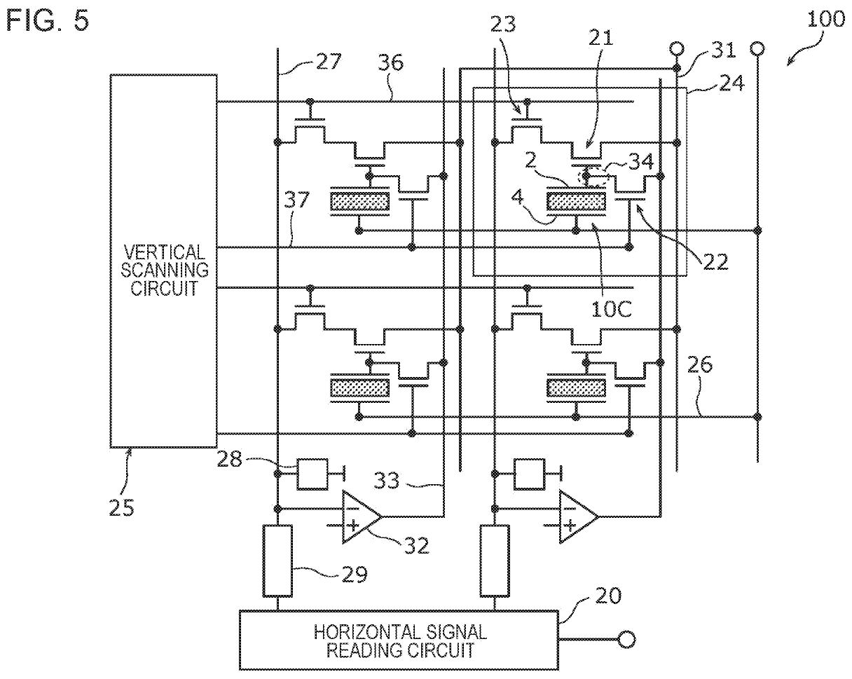

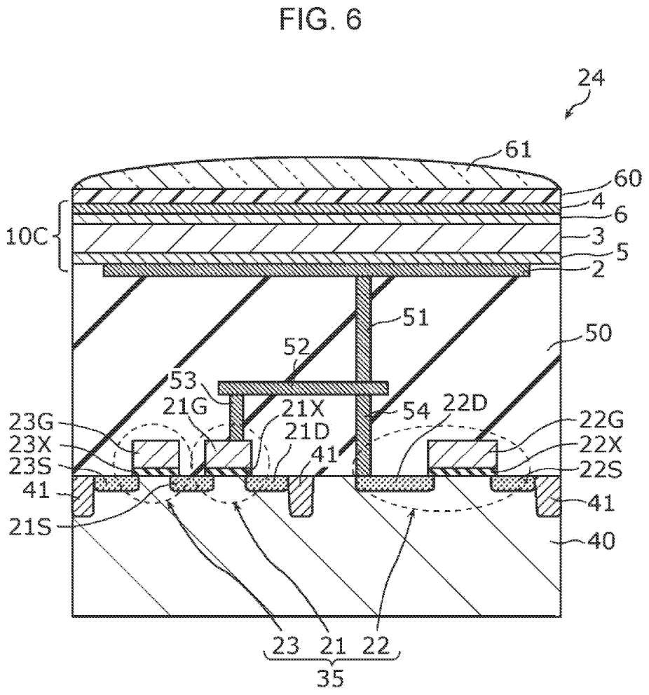

The imaging device according to the embodiment will be described with reference to FIGS. 5 and 6. FIG. 5 is a diagram illustrating an example of a circuit configuration of an imaging device 100 according to the embodiment. FIG. 6 is a schematic sectional view illustrating an example of a device structure of a pixel 24 in the imaging device 100 according to the embodiment.

The imaging device 100 according to the embodiment includes a semiconductor substrate 40 which is one example of the substrate; and a pixel 24 that includes a charge detection circuit 35 provided to the semiconductor substrate 40, a photoelectric conversion unit 10C disposed on the semiconductor substrate 40, and a charge storage node 34 electrically connected to the charge detection circuit 35 and the photoelectric conversion unit 10C. The photoelectric conversion unit 10C of the pixel 24 includes, for example, the above-described photoelectric conversion element 10A or photoelectric conversion element 10B. In the example illustrated in FIG. 6, the photoelectric conversion unit 10C includes the photoelectric conversion element 10B. The charge storage node 34 stores charges generated in the photoelectric conversion unit 10C. The charge detection circuit 35 detects the charges stored in the charge storage node 34. Note that the charge detection circuit 35 provided to the semiconductor substrate 40 may be disposed on the semiconductor substrate 40 or may be disposed directly within the semiconductor substrate 40.

As illustrated in FIG. 5, the imaging device 100 includes a plurality of pixels 24 and peripheral circuits. The imaging device 100 is an organic image sensor implemented by a single-chip integrated circuit and has a pixel array including the plurality of pixels 24 arranged two-dimensionally.

The plurality of pixels 24 are arranged two-dimensionally, specifically, in row and column directions, on the semiconductor substrate 40 to form a photosensitive region which is a pixel region. FIG. 5 illustrates an example in which the pixels 24 are arranged in a matrix of two rows and two columns. Note that, in FIG. 5, the illustration of a circuit for individually setting the sensitivity of the pixels 24 (for example, a pixel electrode control circuit) is omitted for convenience of illustration. Alternatively, the imaging device 100 may be a line sensor. In such a case, the plurality of pixels 24 may be arranged one-dimensionally. Note that, in the present specification, the terms “row direction” and “column direction” refer to a direction in which rows extend and a direction in which columns extend, respectively. Specifically, in FIG. 5, the vertical direction in the drawing sheet is the column direction, and the horizontal direction is the row direction.

As illustrated in FIGS. 5 and 6, each pixel 24 includes the photoelectric conversion unit 10C, the charge detection circuit 35, and the charge storage node 34 electrically connected to the photoelectric conversion unit 10C and the charge detection circuit 35. The charge detection circuit 35 includes an amplification transistor 21, a reset transistor 22, and an address transistor 23.

The photoelectric conversion unit 10C includes a lower electrode 2 provided as a pixel electrode and an upper electrode 4 provided as a counter electrode facing the pixel electrode. A predetermined bias voltage is applied to the upper electrode 4 through a counter-electrode signal line 26.

The lower electrodes 2 are a plurality of pixel electrodes arranged in an array and provided for the plurality of corresponding pixels 24. Each lower electrode 2 is connected to a gate electrode 21G of the amplification transistor 21, and signal charges collected by the lower electrode 2 are stored in the charge storage node 34 located between the lower electrode 2 and the gate electrode 21G of the amplification transistor 21. In this embodiment, the signal charges are holes. Alternatively, the signal charges may be electrons.

The signal charges stored in the charge storage node 34 are applied, as a voltage corresponding to the amount of signal charges, to the gate electrode 21G of the amplification transistor 21. The amplification transistor 21 amplifies this voltage, and the voltage is selectively read as a signal voltage by the address transistor 23. The reset transistor 22, whose source/drain electrode is connected to the lower electrode 2, resets the signal charges stored in the charge storage node 34. That is, the reset transistor 22 resets the potentials of the gate electrode 21G of the amplification transistor 21 and the lower electrode 2.

To perform the above-described operation selectively in the plurality of pixels 24, the imaging device 100 includes power supply lines 31, vertical signal lines 27, address signal lines 36, and reset signal lines 37, and these lines are connected to the pixels 24. Specifically, the power supply lines 31 are connected to the source/drain electrodes of the amplification transistors 21, the vertical signal lines 27 are connected to the source/drain electrodes of the address transistors 23. The address signal lines 36 are connected to gate electrodes 23G of the address transistors 23. The reset signal lines 37 are connected to gate electrodes 22G of the reset transistors 22.

The peripheral circuits include a vertical scanning circuit 25, a horizontal signal reading circuit 20, a plurality of column signal processing circuits 29, a plurality of load circuits 28, and a plurality of differential amplifiers 32. The vertical scanning circuit 25 is also referred to as a row scanning circuit. The horizontal signal reading circuit 20 is also referred to as a column scanning circuit. The column signal processing circuits 29 are also referred to as row signal storage circuits. The differential amplifiers 32 are also referred to as feedback amplifiers.

The vertical scanning circuit 25 is connected to the address signal lines 36 and the reset signal lines 37, selects any of the plurality of pixels 24 arranged in each row in units of row, and reads signal voltages and resets the potentials of the lower electrodes 2. The power supply lines 31 serving as source-follower power supplies supply predetermined power-supply voltages to the pixels 24. The horizontal signal reading circuit 20 is electrically connected to the plurality of column signal processing circuits 29. Each of the column signal processing circuits 29 is electrically connected to the pixels 24 that are arranged in each column through the vertical signal line 27 corresponding to the column. The load circuits 28 are electrically connected to the corresponding vertical signal lines 27. The load circuits 28 and the amplification transistors 21 form source-follower circuits.

The plurality of differential amplifiers 32 are provided so as to correspond to respective columns. Negative input terminals of the differential amplifiers 32 are connected to the corresponding vertical signal lines 27. Output terminals of the differential amplifiers 32 are connected to the pixels 24 through feedback lines 33 provided so as to correspond to respective columns.

The vertical scanning circuit 25 applies, through the address signal lines 36, row selection signals for controlling ON/OFF of the address transistors 23 to the gate electrodes 23G of the address transistors 23. Thus, a row to be read is scanned and selected. Signal voltages are read from the pixels 24 in the selected row to the corresponding vertical signal lines 27. The vertical scanning circuit 25 applies, through the reset signal lines 37, reset signals for controlling ON/OFF of the reset transistors 22 to the gate electrodes 22G of the reset transistors 22. Thus, a row of pixels 24 to be subjected to the reset operation is selected. The vertical signal lines 27 transmit the signal voltages read from the pixels 24 selected by the vertical scanning circuit 25 to the column signal processing circuits 29.

The column signal processing circuits 29 perform, for example, noise suppression signal processing typified by correlated double sampling and analog-digital conversion (A/D conversion).

The horizontal signal reading circuit 20 sequentially reads signals from the plurality of column signal processing circuits 29 to a horizontal common signal line (not illustrated).

The differential amplifiers 32 are connected through the feedback lines 33 to the drain electrodes of the reset transistors 22. Therefore, when the address transistors 23 and the corresponding reset transistors 22 are electrically connected to each other, the differential amplifiers 32 receive, at their negative terminals, output values of the respective address transistors 23. The differential amplifiers 32 each performs a feedback operation such that the gate potential of the corresponding amplification transistor 21 is equal to a predetermined feedback voltage. In this case, the output voltage value of the differential amplifier 32 is 0 V or a positive voltage close to 0 V. The feedback voltage means the output voltage of the differential amplifier 32.

As illustrated in FIG. 6, each pixel 24 includes the semiconductor substrate 40, the charge detection circuit 35, the photoelectric conversion unit 10C, and the charge storage node 34 (refer to FIG. 5).

The semiconductor substrate 40 may be, for example, an insulating substrate having a semiconductor layer on a surface on which a photosensitive region is to be formed, and is, for example, a p-type silicon substrate. The semiconductor substrate 40 includes impurity regions 21D, 21S, 22D, 22S, and 23S and element isolation regions 41 for electrically isolating pixels 24 from each other. The impurity regions 21D, 21S, 22D, 22S, and 23S are, for example, n-type regions. In this embodiment, an element isolation region 41 is disposed between the impurity region 21D and the impurity region 22D. As a result, leakage of the signal charges stored in the charge storage node 34 is suppressed. The element isolation regions 41 are formed by performing, for example, implantation of acceptor ions under predetermined implantation conditions.

The impurity regions 21D, 21S, 22D, 22S, and 23S are, for example, diffusion layers formed within the semiconductor substrate 40. As illustrated in FIG. 6, the amplification transistor 21 includes the impurity regions 21S and 21D and the gate electrode 21G. The impurity region 21S and the impurity region 21D respectively function as, for example, a source region and a drain region of the amplification transistor 21. A channel region of the amplification transistor 21 is formed between the impurity region 21S and the impurity region 21D.

Similarly, the address transistor 23 includes the impurity regions 23S and 21S and the gate electrode 23G connected to one of the address signal lines 36. In this example, the amplification transistor 21 and the address transistor 23 share the impurity region 21S and are thereby electrically connected to each other. The impurity region 23S functions as, for example, a source region of the address transistor 23. The impurity region 23S has connection to one of the vertical signal lines 27 illustrated in FIG. 5.

The reset transistor 22 includes the impurity regions 22D and 22S and the gate electrode 22G connected to one of the reset signal lines 37. The impurity region 22S functions as, for example, a source region of the reset transistor 22. The impurity region 22S has connection to one of the reset signal lines 37 illustrated in FIG. 5.

An interlayer insulating layer 50 is stacked on the semiconductor substrate 40 so as to cover the amplification transistor 21, the address transistor 23, and the reset transistor 22.

A wiring layer (not illustrated) can be disposed within the interlayer insulating layer 50. The wiring layer is formed of a metal such as copper and can include, as a portion thereof, a wiring line such as the above-described vertical signal lines 27, for example. The number of insulating layers within the interlayer insulating layer 50 and the number of layers included in the wiring layer disposed within the interlayer insulating layer 50 may be appropriately set.

Within the interlayer insulating layer 50, a contact plug 54 connected to the impurity region 22D of the reset transistor 22, a contact plug 53 connected to the gate electrode 21G of the amplification transistor 21, a contact plug 51 connected to the lower electrode 2, and a wiring line 52 that connects the contact plug 51, the contact plug 54, and the contact plug 53 together are disposed. In this manner, the impurity region 22D of the reset transistor 22 is electrically connected to the gate electrode 21G of the amplification transistor 21.

The charge detection circuit 35 detects signal charges collected by the lower electrode 2, and outputs a signal voltage. Specifically, the charge detection circuit 35 reads charges generated in the photoelectric conversion unit 10C. The charge detection circuit 35 includes the amplification transistor 21, the reset transistor 22, and the address transistor 23 and is formed in the semiconductor substrate 40.

The amplification transistor 21 includes the impurity region 21D and the impurity region 21S formed within the semiconductor substrate 40 and functioning as a drain region and a source region, respectively, a gate insulating layer 21X formed on the semiconductor substrate 40, and the gate electrode 21G formed on the gate insulating layer 21X.

The reset transistor 22 includes the impurity region 22D and the impurity region 22S formed within the semiconductor substrate 40 and functioning as a drain region and a source region, respectively, a gate insulating layer 22X formed on the semiconductor substrate 40, and the gate electrode 22G formed on the gate insulating layer 22X.

The address transistor 23 includes the impurity regions 21S and 23S formed within the semiconductor substrate 40 and functioning as a drain region and a source region, respectively, a gate insulating layer 23X formed on the semiconductor substrate 40, and a gate electrode 23G formed on the gate insulating layer 23X. The impurity region 21S is shared by the amplification transistor 21 and the address transistor 23, and consequently, the amplification transistor 21 and the address transistor 23 are connected in series.

The above-described photoelectric conversion unit 10C is disposed on the interlayer dielectric layer 50. In other words, in this embodiment, a plurality of pixels 24 forming the pixel array are formed on the semiconductor substrate 40. The plurality of pixels 24 arranged two-dimensionally on the semiconductor substrate 40 form the photosensitive region. The distance between two adjacent pixels 24 (i.e., pixel pitch) may be, for example, about 2 μm.

The photoelectric conversion unit 10C has the structure of the above-described photoelectric conversion element 10A or photoelectric conversion element 10B.

A color filter 60 is formed on the photoelectric conversion unit 10C, and a microlens 61 is formed on the color filter 60. The color filter 60 is formed as, for example, an on-chip color filter by patterning. For example, a photosensitive resin containing a dye or a pigment dispersed therein is used as the material of the color filter 60. The microlens 61 is formed as, for example, an on-chip microlens. For example, an ultraviolet photosensitive material is used as the material of the microlens 61.

The imaging device 100 can be produced by ordinary semiconductor production processes. In particular, when a silicon substrate is used as the semiconductor substrate 40, various silicon semiconductor processes can be utilized to achieve the production.

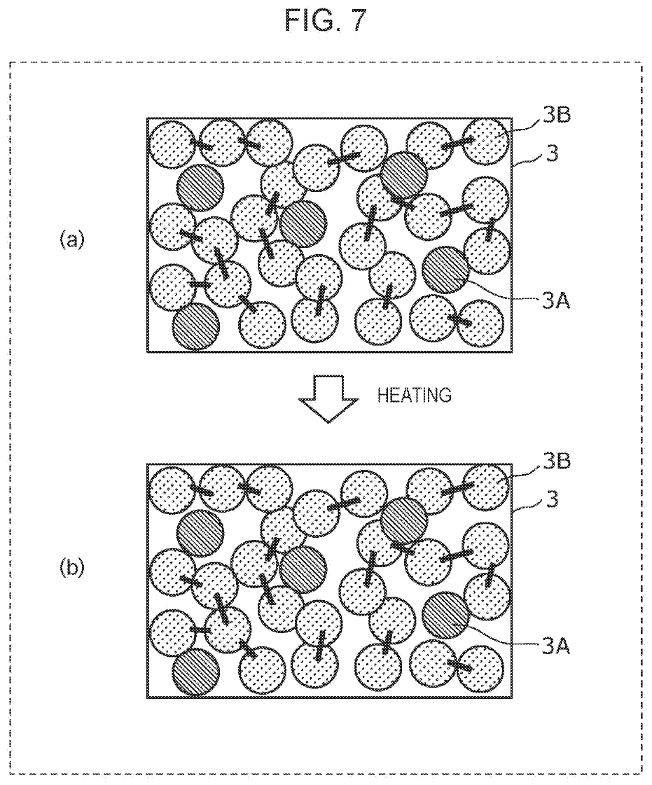

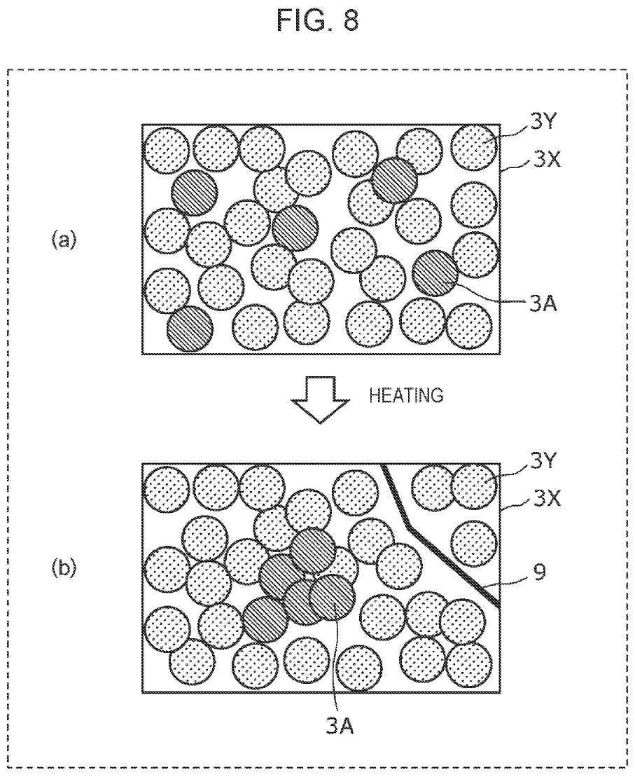

In the imaging device 100, a phthalocyanine derivative or naphthalocyanine derivative and a fullerene polymer are used in the photoelectric conversion layer 3. As a result, even in the case where the imaging device 100 is heated, an increase in the dark current and a decrease in the photoelectric conversion efficiency can be suppressed. This point will be described with reference to the drawings. FIG. 7 is a schematic view illustrating a change in the case where a photoelectric conversion layer 3 containing a fullerene polymer according to this embodiment is heated. FIG. 8 is a schematic view illustrating a change in the case where a photoelectric conversion layer 3X containing no fullerene polymer is heated. FIG. 7 include enlarged partial schematic views of the photoelectric conversion layer 3. FIG. 8 include enlarged partial schematic views of the photoelectric conversion layer 3X. In the photoelectric conversion layer 3X illustrated in FIG. 8, a fullerene or fullerene derivative that is not crosslinked is contained as an acceptor organic semiconductor 3Y instead of the fullerene polymer. In FIG. 7, an acceptor organic semiconductor 3B which is the fullerene polymer is schematically represented by circles shaded with dots and thick solid lines imitating a crosslinking structure. In FIGS. 7 and 8, a donor organic semiconductor 3A which is a phthalocyanine derivative or a naphthalocyanine derivative is schematically represented by circles shaded with oblique lines. In FIG. 8, the acceptor organic semiconductor 3Y which is a fullerene or a fullerene derivative is schematically represented by circles shaded with dots. Part (a) of FIG. 7 illustrates a state immediately after the formation of the photoelectric conversion layer 3, and part (a) of FIG. 8 illustrates a state immediately after the formation of the photoelectric conversion layer 3X. Part (b) of FIG. 7 illustrates a state after the photoelectric conversion layer 3 is heated at 200° C. for 10 minutes, and part (b) of FIG. 8 illustrates a state after the photoelectric conversion layer 3X is heated at 200° C. for 10 minutes.

As illustrated in part (a) of FIG. 7 and part (a) of FIG. 8, before heating, the donor organic semiconductor 3A is dispersed in the whole of the photoelectric conversion layer 3 and the photoelectric conversion layer 3X. As illustrated in part (b) of FIG. 7, in the photoelectric conversion layer 3, the state where the donor organic semiconductor 3A is dispersed in the whole of the photoelectric conversion layer 3 is maintained even after heating. This is probably because the movement of the donor organic semiconductor 3A is limited by the crosslinked fullerene polymer. In contrast, as illustrated in part (b) of FIG. 8, in the photoelectric conversion layer 3X, the donor organic semiconductor 3A is aggregated by heating. Furthermore, in the photoelectric conversion layer 3X, the formation of a crack 9 is observed. Thus, in the photoelectric conversion layer 3 according to this embodiment, the aggregation of the donor organic semiconductor 3A is suppressed even when the photoelectric conversion layer 3 is heated. Furthermore, in the photoelectric conversion layer 3, a crack 9 is unlikely to occur. Therefore, in the imaging device 100 according to the embodiment, even when heating is performed after the formation of the photoelectric conversion layer 3 in order to form, for example, a color filter 60, the aggregation of the donor organic semiconductor 3A in the photoelectric conversion layer 3 can be suppressed to suppress an increase in the dark current and a decrease in the photoelectric conversion efficiency.

As described above, the imaging device 100 according to the embodiment can realize a high photoelectric conversion efficiency and a reduction in the dark current by using the phthalocyanine derivative or naphthalocyanine derivative and the fullerene polymer described above.

### EXAMPLES

Hereinafter, photoelectric conversion elements etc., used for the imaging device according to the present disclosure will be specifically described by way of Examples. However, the present disclosure is not at all limited to the following Examples alone.

### Synthesis of Materials

### Synthesis Example 1

The following compound (A-1), which is the compound represented by structural formula (22) above, was synthesized by the method described in Non Patent Literature 3 using 4,4′-bis(chloromethyl)biphenyl as a starting material.

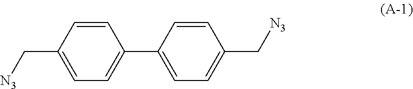 [SMILES: [N-]=[N+]=NCc1ccc(-c2ccc(CN=[N+]=[N-])cc2)cc1]

### Synthesis Example 2

The following compound (A-2), which is the compound represented by structural formula (24) above, was synthesized by the same method as that used in Synthesis Example 1 except that 4,4′-bis(chloromethyl)biphenyl used as the starting material in the synthesis of the compound (A-1) was changed to 4,4′-bis(chloromethyl)phenyl.

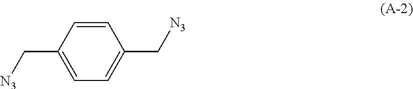 [SMILES: [N-]=[N+]=NCc1ccc(CN=[N+]=[N-])cc1]

The compound was identified by proton nuclear magnetic resonance spectroscopy (¹H NMR). The results are shown below.

¹H NMR (400 MHz, CDCl₃): δ (ppm)=7.34 (4H), 4.36 (4H)

### Synthesis Example 3

The following compound (A-5) which is the compound represented by structural formula (14) above was synthesized by a synthesis procedure below.

### (1) Synthesis of Compound (A-4)

This synthesis was performed with reference to MOHAMED AOUDIA et. al., “Synthesis of a Series of Octabutoxy- and Octabutoxybenzophthalocyanines and Photophysical Properties of Two Members of the Series”, Journal of American Chemical Society, American Chemical Society, 1997, Vol. 119, No. 26, pp. 6029-6039 (Non Patent Literature 4).

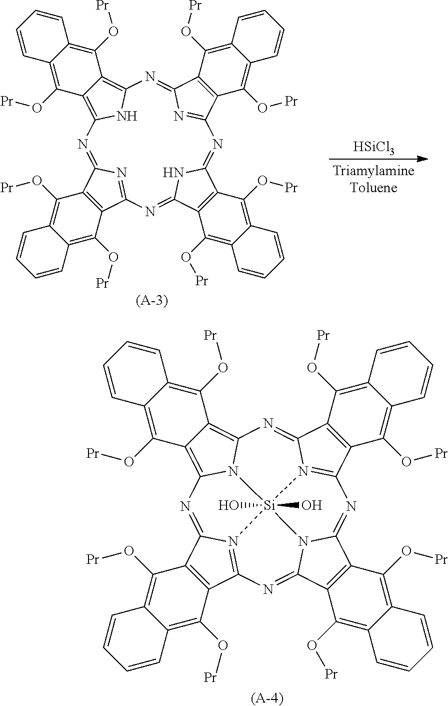

To a 50 mL reaction vessel purged with argon, 50 mg of the above compound (A-3), 5 mL of triamylamine, and 25 mL of dehydrated toluene were added, and 0.5 mL of HSiCl₃ was further added, and stirring was performed under heating at 90° C. for 24 hours.

The reaction solution was allowed to cool to room temperature, 20 mL of distilled water was added to the reaction solution, and stirring was performed for one hour. The reaction solution was extracted with 60 mL of toluene four times. The extracted organic layer was washed with distilled water, and the organic layer was then concentrated to obtain 48 mg of a crude product. The resulting crude product was purified with a neutral alumina column to obtain the target compound (A-4) as a brown solid. The amount of the compound (A-4) was 25 mg, and the yield thereof was 49%.

### (2) Synthesis of Compound (A-5)

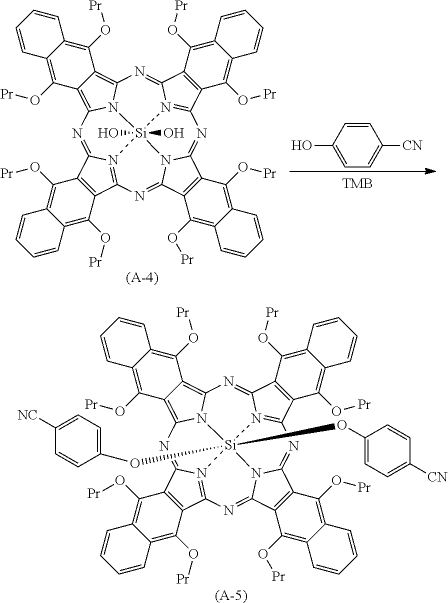

To a 200 mL reaction vessel purged with argon, 0.75 g of the compound (A-4) synthesized as described above and 0.91 g of 4-cyanophenol were added. These compounds were dissolved in 30 mL of 1,2,4-trimethylbenzene (TMB), and the resulting solution was refluxed under heating at 180° C. for three hours. The reaction solution was cooled to room temperature, 50 mL of heptane was then added to the reaction solution to precipitate a solid component, and the precipitated solid component was collected by filtration. The solid component collected by filtration was purified by silica gel column chromatography (where the developing solvent was toluene:ethyl acetate=1:1), and the resulting purified product was further reprecipitated with heptane. The resulting precipitate was dried under reduced pressure at 100° C. for three hours to obtain the target compound (A-5). The amount of the compound (A-5) was 557 mg, and the yield thereof was 74%.

The resulting compound was identified by ¹H NMR and matrix assisted laser desorption/ionization time of flight mass spectrometry (MALDI-TOF-MS). The results are shown below.

¹H NMR (400 MHz, C₆D₆): δ (ppm)=9.11 (8H), 7.58 (8H), 5.58 (4H), 5.06 (16H), 3.70 (4H), 2.24 (16H), 1.11 (24H)

MALDI-TOF-MS actual measured value: m/z=1441.82 (M⁺)

The chemical formula of the compound (A-5) is Cs₆H₈₀N₁₀O₁₀Si, and the exact mass thereof is 1441.82.

It was confirmed from the results that the compound (A-5) was obtained by the above synthesis procedure.

### Synthesis Example 4

The following compound (A-6), which is the compound represented by structural formula (15) above, was synthesized by the following synthesis procedure.

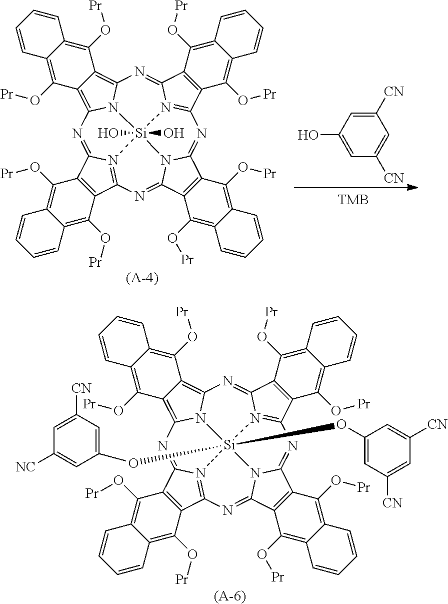

To a 200 mL reaction vessel purged with argon, 0.64 g of the compound (A-4) synthesized in “(1) Synthesis of compound (A-4)” of Synthesis Example 3 above and 1.13 g of 3,5-dicyanophenol were added. These compounds were dissolved in 40 mL of 1,2,4-trimethylbenzene (TMB), and the resulting solution was refluxed under heating at 180° C. for five hours. The reaction solution was cooled to room temperature, 50 mL of heptane was then added to the reaction solution to precipitate a solid component, and the precipitated solid component was collected by filtration. The solid component collected by filtration was purified by silica gel column chromatography (where the developing solvent was dichloromethane), and the resulting purified product was further reprecipitated with heptane. The resulting precipitate was dried under reduced pressure at 100° C. for three hours to obtain the target compound (A-6). The amount of the compound (A-6) was 528 mg, and the yield thereof was 68%.

The resulting compound was identified by ¹H NMR and MALDI-TOF-MS. The results are shown below.

¹H NMR (400 MHz, C₆D₆): δ (ppm)=9.08 (8H), 7.55 (8H), 5.22 (2H), 4.08 (4H), 2.36 (16H), 1.23 (24H)

MALDI-TOF-MS actual measured value: m/z=1491.83 (M⁺)

The chemical formula of the compound (A-6) is C₈₈H₇₈N₁₂O₁₀Si, and the exact mass thereof is 1491.75.

It was confirmed from the results that the compound (A-6) was obtained by the above synthesis procedure.

### Synthesis Example 5

The following compound (A-9), which is the compound represented by structural formula (13) above, was synthesized by the following synthesis procedure.

### (1) Synthesis of Compound (A-8)

This synthesis was performed with reference to Non Patent Literature 4.

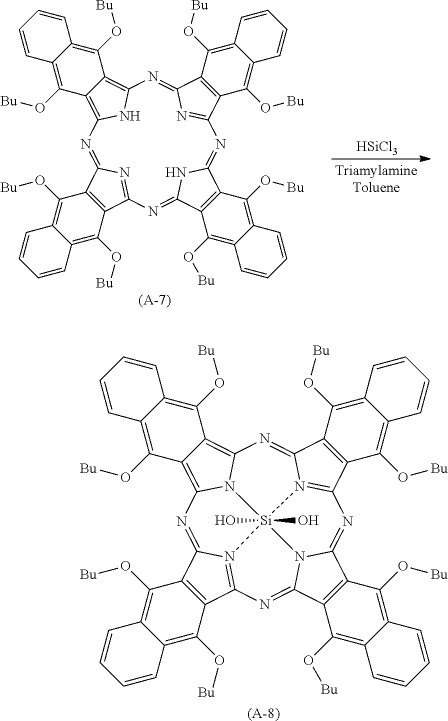

To a 1,000 mL reaction vessel purged with argon, 0.95 g of the above compound (A-7), 92 mL of tributylamine, and 550 mL of dehydrated toluene were added, and 3.7 mL of HSiCl₃ was further added, and stirring was performed under heating at 80° C. for 24 hours. Subsequently, the reaction solution was allowed to cool to room temperature, 3.7 mL of HSiCl₃ was added, and stirring was performed under heating at 80° C. for 24 hours. Subsequently, the reaction solution was allowed to cool to room temperature, 1.9 mL of HSiCl₃ was added, and stirring was performed under heating at 80° C. for 24 hours.

The reaction solution was allowed to cool to room temperature, 360 mL of distilled water was added to the reaction solution, and stirring was performed for one hour. To the resulting reaction solution, 180 mL of triethylamine was added, and the reaction solution was extracted with 100 mL of toluene four times. The extracted organic layer was washed with distilled water, and the washed organic layer was concentrated to obtain 1.54 g of a crude product. The resulting crude product was purified with a neutral alumina column to obtain the target compound (A-8) as a brown solid. The amount of the compound (A-8) was 0.53 g, and the yield thereof was 50%.

### (2) Synthesis of Compound (A-9)

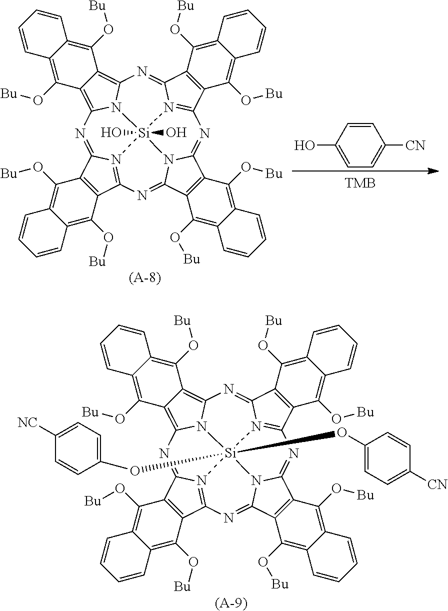

To a 200 mL reaction vessel purged with argon, 0.2 g of the compound (A-8) synthesized as described above and 0.88 g of 4-cyanophenol were added. These compounds were dissolved in 15 mL of 1,2,4-trimethylbenzene (TMB), and the resulting solution was refluxed under heating at 180° C. for three hours. The reaction solution was cooled to room temperature, 30 mL of methanol was then added to the reaction solution to precipitate a solid component, and the precipitated solid component was collected by filtration. The solid component collected by filtration was purified by silica gel column chromatography (where the developing solvent was toluene), and the resulting purified product was further reprecipitated with methanol. The resulting precipitate was dried under reduced pressure at 100° C. for three hours to obtain the target compound (A-9). The amount of the compound (A-9) was 159 mg, and the yield thereof was 69%.

The resulting compound was identified by ¹H NMR and MALDI-TOF-MS. The results are shown below.

¹H NMR (400 MHz, C₆D₆): δ (ppm)=9.14 (8H), 7.60 (8H), 5.65 (4H), 5.11 (16H), 3.75 (4H), 2.28 (16H), 1.62 (16H), 0.98 (24H)

MALDI-TOF-MS actual measured value: m/z=1553.95 (M⁺)

The chemical formula of the compound (A-9) is C₉₄H₉₆N₁₀O₁₀Si, and the exact mass thereof is 1553.71.

It was confirmed from the results that the compound (A-9) was obtained by the above synthesis procedure.

### Photoelectric Conversion Element

Hereinafter, photoelectric conversion elements according to the present disclosure will be more specifically described with reference to Examples 1, 2, 3 and Comparative Examples 1 and 2.

### Example 1

### Production of Photoelectric Conversion Element

A photoelectric conversion element was produced by the following procedure. The production of the photoelectric conversion element was conducted in a nitrogen atmosphere throughout the process.

A glass substrate having a thickness of 0.7 mm and having, as a lower electrode, an ITO film with a thickness of 150 nm on one main surface thereof was prepared. In a nitrogen atmosphere in a glove box, an o-xylene solution of 10 mg/mL of VNPB (N4,N4′-di(naphthalen-1-yl)-N4,N4′-bis(4-vinylphenyl)biphenyl-4,4′-diamine, manufactured by LUMTEC) was applied onto the lower electrode by a spin-coating method to form an electron-blocking layer. After this film formation, VNPB was crosslinked by heating at 200° C. for 50 minutes with a hot plate to insolubilize the electron-blocking layer. Subsequently, a blend film which was to become a photoelectric conversion layer was formed by a spin-coating method using a chloroform mixed solution containing the compound (A-5) serving as a donor organic semiconductor, PCBM serving as a raw material of an acceptor organic semiconductor, and the compound (A-1) serving as a crosslinking agent for crosslinking PCBM. The thickness of the blend film obtained at this time was about 150 nm. The weight ratio of the compound (A-5), PCBM, and the compound (A-1) in the chloroform mixed solution was 1:9:1.

Subsequently, the blend film was heated at 150° C. for 10 minutes with a hot plate to crosslink PCBM to obtain a photoelectric conversion layer containing a fullerene polymer composed of crosslinked PCBM.

Furthermore, chloroaluminum phthalocyanine (ClAlPc) was deposited as a hole-blocking layer so as to have a thickness of 30 nm through a metal shadow mask by a vacuum deposition method.

Subsequently, an Al electrode having a thickness of 80 nm was deposited as an upper electrode on the hole-blocking layer. The Al electrode was deposited at a degree of vacuum of less than or equal to 5.0×10⁻⁴ Pa at a deposition rate of 1 Å/s. As a result, a photoelectric conversion element of Example 1 was obtained.

### Evaluations of Characteristics of Photoelectric Conversion Element

As the evaluations of characteristics of the obtained photoelectric conversion element, the dark current and photoelectric conversion efficiency were evaluated by the methods described below. In the characteristic evaluations, the produced photoelectric conversion element was heated at 200° C. for 10 minutes with a hot plate in a glove box, and characteristics before heating (i.e., initial characteristics) and characteristics after heating were evaluated.

### (A) Measurement of Dark Current

For the obtained photoelectric conversion element, the dark current was measured. The measurement was performed with a B1500A semiconductor device parameter analyzer (manufactured by Keysight Technologies) in a nitrogen atmosphere in a glove box. Table 1 shows the value of dark current when a voltage of 10 V was applied.

### (B) Measurement of Photoelectric Conversion Efficiency

For the obtained photoelectric conversion element, the photoelectric conversion efficiency was measured. Specifically, the photoelectric conversion element was placed in a measurement jig that could be hermetically sealed in a nitrogen atmosphere in a glove box, and an external quantum efficiency (EQE) was measured under a voltage condition of 10 V with a long wavelength-sensitive spectral sensitivity measurement system (CEP-25RR, manufactured by Bunkoukeiki Co., Ltd.). Table 1 shows the external quantum efficiency at the wavelength of the obtained maximum peak in the near-infrared light region (peak EQE).

### Example 2

A photoelectric conversion element was produced by the same method as that used in Example 1 except that the compound (A-2) was used as the crosslinking agent. For the obtained photoelectric conversion element, the evaluation of the characteristic evaluations were conducted by the same methods as those used in Example 1. Table 1 shows the results of the characteristic evaluations.

### Comparative Example 1

A photoelectric conversion element was produced by the same method as that used in Example 1, except that, in the formation of the photoelectric conversion layer, a chloroform mixed solution that did not contain the compound (A-1) serving as the crosslinking agent and that contained the compound (A-5) and PCBM at a weight ratio of 1:9 was used, so that PCBM was not crosslinked. For the obtained photoelectric conversion element, the characteristic evaluations were conducted by the same methods as those used in Example 1. Table 1 shows the results of the characteristic evaluations.

### Example 3

A photoelectric conversion element was produced by the same method as that used in Example 1 except that the compound (A-6) was used as the donor organic semiconductor instead of the compound (A-5). For the obtained photoelectric conversion element, the characteristic evaluations were conducted by the same methods as those used in Example 1. Table 1 shows the results of the characteristic evaluations.

### Comparative Example 2

A photoelectric conversion element was produced by the same method as that used in Example 3, except that, in the formation of the photoelectric conversion layer, a chloroform mixed solution that did not contain the compound (A-1) serving as the crosslinking agent and that contained the compound (A-6) and PCBM at a weight ratio of 1:9 was used, so that PCBM was not crosslinked. For the obtained photoelectric conversion element, the characteristic evaluations were conducted by the same methods as those used in Example 1. Table 1 shows the results of the characteristic evaluations.

The above results are summarized in Table 1 below. In Table 1, “-” represents that the characteristic could not be evaluated.

TABLE 1

| | | | | | Characteristics after | |
|---|---|---|---|---|---|---|
| | | | Initial characteristics | | heating | |
| | | | | Peak | | Peak |
| | Donor organic | | Dark current | EQE | Dark current | EQE |
| | semiconductor | Crosslinking | @ 10 V | @ 10 V | @ 10 V | @ 10 V |
| | material | agent | [mA/cm²] | [%] | [mA/cm²] | [%] |
| Example 1 | Compound | Compound | 5.0 × 10⁻⁷ | 39 | 1.6 × 10⁻⁶ | 43 |
| | (A-5) | (A-1) | | | | |
| Example 2 | Compound | Compound | 4.0 × 10⁻⁷ | 42 | 9.2 × 10⁻⁷ | 41 |
| | (A-5) | (A-2) | | | | |
| Comparative | Compound | None | 8.0 × 10⁻⁷ | 49 | — | — |
| Example 1 | (A-5) | | | | | |
| Example 3 | Compound | Compound | 1.0 × 10⁻⁶ | 32 | 2.0 × 10⁻⁶ | 30 |
| | (A-6) | (A-1) | | | | |
| Comparative | Compound | None | 3.0 × 10⁻⁶ | 40 | — | — |
| Example 2 | (A-6) | | | | | |

As in the photoelectric conversion elements of Examples 1 to 3, when a fullerene polymer was formed using a crosslinking agent, the characteristics hardly changed before and after heating. On the other hand, in the case of the photoelectric conversion elements of Comparative Examples 1 and 2, which included no fullerene polymer, in the evaluations after heating, an excessive current flowed due to short circuit in both the dark state and the bright state, and the characteristics could not be evaluated. Furthermore, in the photoelectric conversion elements of Comparative Examples 1 and 2, the formation of cracks was observed in the photoelectric conversion layer after heating.

It was confirmed from the above results that the degradation of characteristics, that is, a decrease in the external quantum efficiency and an increase in the dark current, due to heating could be suppressed by using the crosslinking agent as a material of the photoelectric conversion layer to form the fullerene polymer.

It was also confirmed that the photoelectric conversion elements of Examples 1 to 3 could realize a high external quantum efficiency greater than or equal to 30% even after heating.

Thus, the use of the photoelectric conversion elements of Examples 1 to 3 enables realization of imaging devices having a high photoelectric conversion efficiency and capable of suppressing dark current.

The imaging device according to the present disclosure has been described on the basis of the embodiments and Examples; however, the present disclosure is not limited to the embodiments and Examples. Various modifications to the embodiments and Examples that are conceivable by a person skilled in the art and other embodiments constructed by combining some of components in the embodiments and Examples are also included in the scope of the present disclosure, so long as they do not depart from the spirit of the present disclosure.

The imaging device according to the present disclosure is applicable to, for example, an image sensor, and in particular, to an image sensor having high photoelectric conversion characteristics in the near-infrared light region.

What is claimed is:

1. An imaging device comprising:
a photoelectric conversion element that includes a first electrode, a second electrode facing the first electrode, and a photoelectric conversion layer located between the first electrode and the second electrode; and
a charge detection circuit that reads a charge generated in the photoelectric conversion element, wherein
the photoelectric conversion layer is a bulk heterojunction layer that contains a phthalocyanine derivative or a naphthalocyanine derivative and a fullerene polymer, and
in the fullerene polymer, a fullerene or a fullerene derivative is crosslinked by a crosslinking structure represented by general formula (1) below: [symbol]
NCH₂XCH₂N [symbol] (1)
where X is a bifunctional functional group.

2. The imaging device according to claim 1,
wherein in general formula (1), X is an alkylene group or an arylene group.

3. The imaging device according to claim 1,
wherein the photoelectric conversion layer contains a compound represented by general formula (2) below as the phthalocyanine derivative or a compound represented by general formula (3) below as the naphthalocyanine derivative, 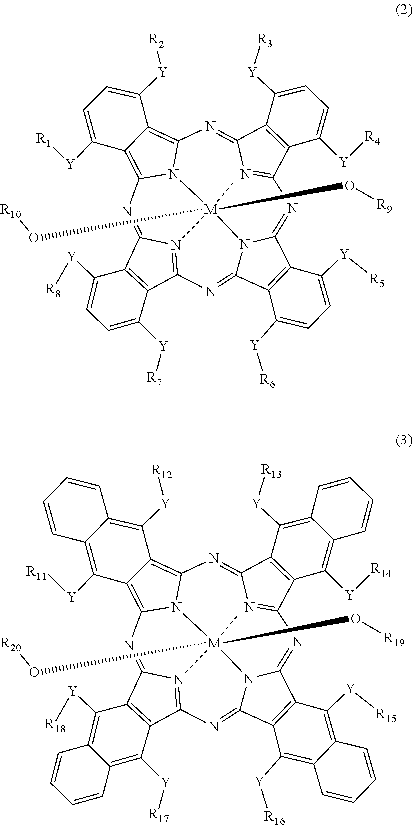
where R₁ to R₈ and R₁₁ to R₁₈ are each independently an alkyl group; M is Si or Sn; Y is S or O; Z is S or O; and R₉, R₁₀, R₁₉, and R₂₀ are each any one of substituents represented by general formulae (4) to (6) below: 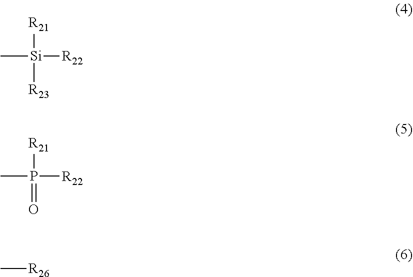
where R₂₁ to R₂₃ are each independently an alkyl group or an aryl group; and R₂₄ to R₂₆ are each independently an aryl group.

4. The imaging device according to claim 3,
wherein in general formulae (2) and (3), M is Si, Y is S, and Z is O.

5. The imaging device according to claim 1,
wherein the photoelectric conversion element further includes a charge-blocking layer between the photoelectric conversion layer and one of the first electrode and the second electrode.
